(19) United States
(12) Patent Application Publication
(10) Pub. No.: US 2026/0323971 A1
(43) Pub. Date: Oct. 15, 2026

(54) CAPACITOR

(71) Applicant: ELSPES Inc., Daejeon (KR)

(72) Inventors: Dong Ki LEE, Hwaseong-si (KR); Su Bin KO, Hwaseong-si (KR); Tae Dong KIM, Hwaseong-si (KR); Yeong Lyeol PARK, Yongin-si (KR); Eun Joo KO, Hwaseong-si (KR); Ui Hwan KIM, Hwaseong-si (KR)

(21) Appl. No.: 19/552,349

(22) Filed: Feb. 27, 2026

(30) Foreign Application Priority Data
Apr. 14, 2025 (KR) 10-2025-0048074

(51) Int. Cl. H10D 1/68; H10W 20/20; H10W 20/40

(52) U.S. Cl. CPC H10D 1/716; H10W 20/211; H10W 20/496

(57) ABSTRACT

The present disclosure relates to a capacitor. A capacitor of the present disclosure includes a substrate, at least three first metal layers disposed in a first trench formed on the substrate, and first dielectric layers disposed between the at least three first metal layers, wherein the at least three first metal layers consist of a first electrode, a second electrode disposed on the first electrode, and at least one first floating metal layer disposed between the first electrode and the second electrode, and by including a floating metal layer disposed between dielectric layers, the capacitor can secure an excellent withstand voltage characteristic and insulation reliability even in a structure including thin dielectric layers.

### CROSS-REFERENCE TO RELATED APPLICATION

This application claims priority to and the benefit of Korean Patent Application No. 2025-0048074, filed on Apr. 14, 2025, the disclosure of which is incorporated herein by reference in its entirety.

### BACKGROUND

### 1. Field of the Invention

The present disclosure relates to a capacitor, and more particularly, to a silicon trench capacitor including a floating metal layer.

### 2. Discussion of Related Art

In recent years, with rapid progress in increasing the capacity and integration of electronic devices, demand for size reduction and performance enhancement of various parts mounted in electronic devices has increased. In particular, with demand for high-speed data processing and radio-frequency operation of portable electronic devices along with commercialization of 5G mobile communication technology, performance of passive elements applied to the electronic devices is also being enhanced. For example, the number of used passive elements, such as capacitors used for power stabilization, filtering, radio-frequency matching etc., is gradually increasing, and high-capacity, high-performance characteristics are required. However, on the other hand, as size reduction of portable electronic devices continues, there is a limit in an area of a substrate on which parts can be mounted, and thus there is an increasing need for technologies for reducing the size and increasing the integration for increasing a capacity per unit area of a passive element.

Accordingly, a trench capacitor that is formed in a vertical direction in a semiconductor substrate has been proposed. The trench capacitor can have a higher capacitance in the same area compared to existing planar capacitors by securing a surface area between electrodes in the vertical direction of the substrate. However, numerous technical difficulties and limitations exist in further increasing the capacitance per unit area of a trench capacitor. In particular, in a trench capacitor, a dielectric layer and a metal electrode layer should be deposited thinly and uniformly in a deep, narrow trench structure. In this process, it is very important not only to secure the thickness uniformity of a thin film, but also to improve a step-coverage characteristic that allows a film to be evenly formed even on sidewalls and a bottom of a trench. However, a difficulty level of a deposition process further increases with an increase in the aspect ratio of a trench, and there are also limitations in terms of securing film quality and process repeatability.

Therefore, there is a need for a technology for addressing the above-described problems.

Meanwhile, the above-described background art is technical information that was possessed by the inventors to derive the present disclosure or acquired by the inventors in the course of deriving the present disclosure, and the background art is not necessarily a known art that was open to the general public prior to filing of the present disclosure.

### RELATED ART DOCUMENT

### PATENT DOCUMENT

(Patent Document 1) Korean Unexamined Patent Application Publication No. 2016-0090582 (Aug. 01, 2016)

### SUMMARY OF THE INVENTION

The present disclosure is directed to providing a trench capacitor that can have a higher capacitance in the same area compared to existing planar capacitors.

The present disclosure is also directed to providing a capacitor in which a dielectric layer and a metal electrode layer are deposited thinly and uniformly in a trench, and a method of manufacturing the same.

The present disclosure is also directed to addressing problems of dielectric breakdown and withstand voltage degradation that may occur when a dielectric layer of a trench capacitor is formed to be thin.

Objectives of the present disclosure are not limited to those mentioned above, and other unmentioned objectives should be clearly understood by those of ordinary skill in the art from the description below.

According to one aspect of the present disclosure, there is provided a capacitor including a substrate, at least three first metal layers disposed in a first trench formed on the substrate, and first dielectric layers disposed between the at least three first metal layers, wherein the at least three first metal layers consist of a first electrode, a second electrode disposed on the first electrode, and at least one first floating metal layer disposed between the first electrode and the second electrode.

According to another aspect of the present disclosure, the capacitor may further include an insulating layer disposed on the second electrode, a first metal pattern disposed on an upper surface of the insulating layer, a second metal pattern disposed to be spaced from the first metal pattern on the upper surface of the insulating layer, a first via disposed between the first metal pattern and the first electrode, and a second via disposed between the second metal pattern and the second electrode, and the first via may be disposed to pass through the second electrode and the at least one first floating metal layer.

According to still another aspect of the present disclosure, on a plane of the substrate, an area of the at least one first floating metal layer may be greater than an area of the first electrode and an area of the second electrode.

According to yet another aspect of the present disclosure, the capacitor may further include a second trench disposed to be spaced from the first trench on an upper surface of the substrate, at least three second metal layers disposed in the second trench, and second dielectric layers disposed between the at least three second metal layers, wherein the at least three second metal layers consist of a third electrode, a fourth electrode disposed on the third electrode, and at least one second floating metal layer disposed between the third electrode and the fourth electrode, and the at least one first floating metal layer and the at least one second floating metal layer may be connected to each other.

According to yet another aspect of the present disclosure, the at least three first metal layers may further include a fifth electrode, the fifth electrode may be electrically connected to the first electrode, and the at least one first floating metal layer may be disposed between the first electrode and the fifth electrode.

According to yet another aspect of the present disclosure, the at least three first metal layers may further include a sixth electrode, the sixth electrode may be electrically connected to the second electrode, and the at least one first floating metal layer may be disposed between the second electrode and the sixth electrode.

According to yet another aspect of the present disclosure, the first electrode may be a metal layer disposed at a lowermost layer among the at least three first metal layers, and the second electrode may be a metal layer disposed at an uppermost layer among the at least three first metal layers.

According to yet another aspect of the present disclosure, the capacitor may further include a conductive layer disposed on the upper surface of the substrate and a first pad electrically connected to the first electrode, and the conductive layer may electrically connect the first electrode and the first pad.

According to yet another aspect of the present disclosure, the capacitor may further include a third via that passes through the substrate and a first pad electrically connected to the first electrode, and the third via may electrically connect the first electrode and the first pad.

According to yet another aspect of the present disclosure, the first pad may be disposed on a lower surface of the substrate.

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a cross-sectional view of a capacitor according to one embodiment of the present disclosure;

FIG. 2 is a cross-sectional view for describing a capacitor including an extending floating metal layer according to another embodiment of the present disclosure;

FIG. 3 is a cross-sectional view for describing a capacitor including a floating metal layer connected to another floating metal layer according to still another embodiment of the present disclosure;

FIG. 4 is a cross-sectional view for describing a capacitor in which a floating metal layer is disposed between electrodes connected to each other according to yet another embodiment of the present disclosure;

FIG. 5 is a cross-sectional view for describing another capacitor in which a floating metal layer is disposed between electrodes connected to each other according to yet another embodiment of the present disclosure;

FIG. 6 is a cross-sectional view for describing a capacitor in which a conductor is disposed on an upper surface of a substrate according to yet another embodiment of the present disclosure; and

FIG. 7 is a cross-sectional view for describing a capacitor in which a via passing through a substrate is disposed according to yet another embodiment of the present disclosure.

### DETAILED DESCRIPTION OF EXEMPLARY EMBODIMENTS

Advantages and features of the present disclosure and methods of achieving them will become apparent with reference to the embodiments described below in detail in conjunction with the accompanying drawings. However, the present disclosure is not limited to the embodiments disclosed below, but may be implemented in various different forms, and these embodiments are provided only to allow the disclosure of the present disclosure to be complete, and to completely inform those of ordinary skill in the art to which the present disclosure pertains of the scope of the disclosure, and the present disclosure is only defined by the scope of the claims.

Since the shapes, sizes, proportions, angles, numbers, and the like disclosed in the drawings for describing embodiments of the present disclosure are only examples, the present disclosure is not limited to the illustrated items. Further, in describing the present disclosure, when it is determined that a detailed description of related known technology may unnecessarily obscure the gist of the present disclosure, the detailed description thereof will be omitted. Where “including,” “having,” “consisting of,” and the like are used in the present disclosure, other parts may be added unless a more limiting term like “only” is used. A case in which a component is expressed in a singular form includes a plural form, and vice versa, unless explicitly stated otherwise.

In interpreting the components, it should be understood that an error range is included even when there is no separate explicit description.

Although the terms “first,” “second,” and the like may be used to describe various components, these components are not limited by these terms. These terms are only used to distinguish one component from another component. Accordingly, a first component mentioned below may also be a second component, and vice versa, within the technical spirit of the present disclosure.

The same reference numerals indicate the same components throughout the disclosure unless otherwise specified.

Features of various embodiments of the present disclosure may be partially or entirely coupled or combined with each other, and technically, various linkages and operations are possible as can be readily understood by those of ordinary skill in the art, and the embodiments may be implemented independently of each other or together in an interrelated relationship.

Hereinafter, the present disclosure will be described in detail with reference to the accompanying drawings.

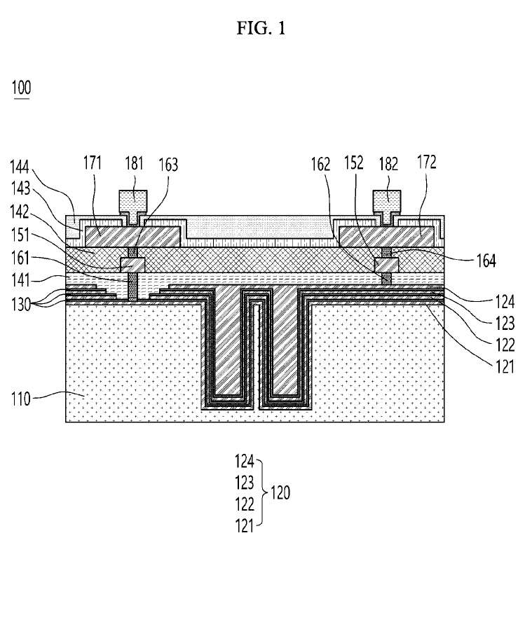

FIG. 1 is a cross-sectional view of a capacitor according to one embodiment of the present disclosure.

Referring to FIG. 1, a capacitor 100 includes a substrate 110, metal layers 120, and dielectric layers 130. In some cases, the capacitor 100 may further include insulating layers 141, 142, 143, and 144, metal patterns 151, 152, 171, and 172, vias 161 and 162, or pads 181 and 182.

The substrate 110 may include various materials according to the type and required characteristics of the capacitor 100. For example, the substrate 110 may include Si, SiC, Al₂O₃, GaAs, GaN, InP, InAs or InSb. Preferably, the substrate 110 may be a Si wafer.

The substrate 110 includes a trench formed on one surface. For example, the substrate 110 may include at least one trench formed on an upper surface.

Referring to FIG. 1, the metal layers 120 may be disposed in the trench of the substrate 110. Specifically, the metal layers 120 may be stacked to correspond to the shapes of the upper surface and the trench of the substrate 110 in the upper surface and the trench of the substrate 110.

The metal layers 120 may consist of at least three metal layers. Specifically, the metal layers 120 may consist of four metal layers that are sequentially stacked. For example, the metal layers 120 may consist of a first metal layer 121, a second metal layer 122, a third metal layer 123, and a fourth metal layer 124.

The metal layers 120 may include a first electrode, a second electrode, and at least one floating metal layer. Specifically, the metal layers 120 may consist of a first electrode, a second electrode disposed on the first electrode, and at least one floating metal layer disposed between the first electrode and the second electrode. More specifically, the metal layers 120 may consist of a first electrode that is disposed at a lowermost layer, a second electrode that is disposed at an uppermost layer, and at least one floating metal layer disposed between the first electrode and the second electrode. For example, the first metal layer 121 may be the first electrode, the fourth metal layer 124 may be the second electrode, and the second metal layer 122 or the third metal layer 123 may be the floating metal layer. In some cases, the first metal layer 121 may be the first electrode, the third metal layer 123 may be the second electrode, and the second metal layer 122 may be the floating metal layer. The present embodiment will be described based on an example in which the first metal layer 121 is the first electrode, and the fourth metal layer 124 is the second electrode.

In some cases, one or more floating metal layers may be disposed at uniform intervals between the first electrode and the second electrode. Specifically, the dielectric layers 130 disposed between the metal layers 120 may all have the same thickness, and intervals between each floating metal layer and the first electrode and the second electrode may be formed equally. For example, an interval between the first metal layer 121, which is the first electrode, and the second metal layer 122, which is the floating metal layer, an interval between the second metal layer 122, which is the floating metal layer, and the third metal layer 123, which is the floating metal layer, and an interval between the third metal layer 123, which is the floating metal layer, and the fourth metal layer 124, which is the second electrode, may all be the same.

By including the floating metal layer disposed between the first electrode and the second electrode, the capacitor 100 according to one embodiment of the present disclosure can distribute an electric field and a voltage applied to the dielectric layers 130 and can mitigate electric field distribution. Accordingly, by including the floating metal layer that mitigates electric field distribution between the electrodes, the capacitor 100 can suppress local electric field concentration and can reduce the possibility of dielectric breakdown in the dielectric layers. As a result, breakdown voltage and withstand voltage characteristics of the capacitor 100 can be improved, and insulation reliability and service life of elements of the capacitor 100 can be increased.

Also, by including the floating metal layer disposed between the first electrode located at the lowermost layer and the second electrode located at the uppermost layer, the capacitor 100 according to one embodiment of the present disclosure can have a plurality of floating metal layers disposed between the first electrode and the second electrode and can more efficiently improve the breakdown voltage and withstand voltage characteristics.

Also, by including one or more floating metal layers disposed at uniform intervals, the capacitor 100 according to one embodiment of the present disclosure allows a voltage applied to the capacitor 100 to be equally distributed to a plurality of dielectric layers 130. Accordingly, the capacitor 100 can prevent a problem in which an electric field is concentrated on the dielectric layer 130 at a specific layer and local dielectric breakdown occurs. Therefore, by equally distributing the applied voltage to the plurality of dielectric layers 130, the breakdown voltage and withstand voltage characteristics of all elements of the capacitor 100 can be improved, and a speed of deterioration of the dielectric layers 130 can be reduced.

The metal layers 120 may include various conductive materials. Specifically, the metal layers 120 may include a metal film, a metal oxide film, a metal nitride film, or a metal oxynitride film. For example, the metal layers 120 may include TiN, WN, or TaN.

Referring to FIG. 1, the dielectric layers 130 may be disposed between the metal layers 120. For example, the dielectric layers 130 may be disposed between the first metal layer 121 and the second metal layer 122, between the second metal layer 122 and the third metal layer 123, and between the third metal layer 123 and the fourth metal layer 124. That is, the metal layers 120 and the dielectric layers 130 may be alternately stacked in the trench of the substrate 110.

The dielectric layers 130 may serve as dielectrics of the capacitor. Specifically, the dielectric layers 130 may serve as dielectrics that form a capacitance between two electrodes between the first electrode and the second electrode of the capacitor 100.

The dielectric layers 130 may include various dielectric materials. Specifically, the dielectric layers 130 may include a silicon oxide, a silicon nitride, or a high-permittivity material. For example, the dielectric layers 130 may include SiO₂, Si₃N₄, Al₂O₃, HfO₂ or Ta₂O₅ materials.

The dielectric layers 130 may be formed through various deposition processes. For example, the dielectric layers 130 may be formed through any one of a chemical vapor deposition (CVD) process, a physical vapor deposition (PVD) process, and an atomic layer deposition (ALD) process. Preferably, the dielectric layers 130 may be formed through the ALD process. The ALD process may conformally form the dielectric layers 130 through deposition control in units of atomic layers. By including the dielectric layers 130 formed through the ALD process, the capacitor 100 according to one embodiment of the present disclosure can have improved film quality uniformity of the dielectric layers 130 throughout the trench structure. Accordingly, the capacitor 100 can secure insulation reliability of the dielectric layers 130 and improve stability of electrical characteristics.

When the dielectric layers 130 are formed thinly, a dielectric breakdown problem may occur due to overvoltage application or an electric field concentration phenomenon. In particular, in the case of a trench capacitor, due to a problem in which mechanical stress concentration of the dielectric layers 130 increases at corners of the trench, there may be difficulty in thickly forming the dielectric layers 130, and there may be a limitation in improving the breakdown voltage and withstand voltage characteristics. On the other hand, by including the floating metal layers 122 and 123 disposed between the first electrode and the second electrode and between the dielectric layer 130 and another dielectric layer 130, the capacitor 100 according to one embodiment of the present disclosure can distribute the electric field and voltage applied to the dielectric layers 130. Therefore, even in a structure including thin dielectric layers 130, the capacitor 100 can secure an excellent withstand voltage characteristic and insulation reliability.

Referring to FIG. 1, a first insulating layer 141 may be disposed on an upper surface of the metal layers 120. Specifically, the first insulating layer 141 may be disposed to cover the entire upper surface of the metal layers 120.

The first insulating layer 141 may include various insulating materials. Specifically, the first insulating layer 141 may include a silicon oxide, a silicon nitride, or a low-permittivity material. For example, the first insulating layer 141 may include SiO₂, Si₃N₄, or SiOₓN_{y}.

Referring to FIG. 1, metal patterns 151 and 152 may be disposed on the first insulating layer 141. Specifically, a first metal pattern 151 and a second metal pattern 152 may be disposed on an upper surface of the first insulating layer 141.

The first metal pattern 151 and the second metal pattern 152 may be disposed to be spaced from each other. Specifically, the first metal pattern 151 and the second metal pattern 152 may be disposed to be spaced from each other on the upper surface of the first insulating layer 141 to overlap the metal layers 120 in a direction perpendicular to the plane of the substrate 110.

Referring to FIG. 1, vias 161 and 162 may be disposed between the metal patterns 151 and 152 and the metal layers 120. Specifically, a first via 161 may be disposed between the first metal pattern 151 and the first metal layer 121, and a second via 162 may be disposed between the second metal pattern 152 and the fourth metal layer 124. More specifically, the first via 161 may be disposed to pass through the metal layers 120 and the first insulating layer 141 located between the first metal pattern 151 and the first metal layer 121, and the second via 162 may be disposed to pass through the first insulating layer 141 located between the second metal pattern 152 and the fourth metal layer 124. For example, the first via 161 may be disposed to pass through the first insulating layer 141, the fourth metal layer 124, the third metal layer 123, and the second metal layer 122. That is, the first via 161 may be disposed to pass through the second metal layer 122 or the third metal layer 123, which is the floating metal layer. Specifically, the first via 161 may be disposed to simultaneously pass through the fourth metal layer 124, which is the second electrode, and the second metal layer 122 or the third metal layer 123, which is the floating metal layer.

By passing through the floating metal layer as well as the second electrode, the first via 161 of the capacitor 100 according to one embodiment of the present disclosure can mitigate an electric field intensity concentrated on portions around a through-hole of the second electrode. Accordingly, by suppressing a local electric field concentration phenomenon at an edge of the through-hole through the floating metal layer, the capacitor 100 can reduce the risk of dielectric breakdown in the corresponding region. Therefore, even in a high-voltage application environment, the capacitor 100 can reduce the possibility of occurrence of local deterioration and discharge of the dielectric layers 130 and can improve the withstand voltage characteristic and insulation reliability.

The first via 161 and the second via 162 may include a conductive material. The first via 161 may be a conductive via and may electrically connect the first metal layer 121 and the first metal pattern 151, and the second via 162 may be a conductive via and may electrically connect the fourth metal layer 124 and the second metal pattern 152. That is, the first via 161 may electrically connect the first electrode and a first pad 181 corresponding to the first electrode by electrically connecting the first electrode and the first metal pattern 151, and the second via 162 may electrically connect the second electrode and a second pad 182 corresponding to the second electrode by electrically connecting the second electrode and the second metal pattern 152.

Referring to FIG. 1, a second insulating layer 142 may be disposed on the first metal pattern 151 and the second metal pattern 152. Specifically, the second insulating layer 142 may be disposed on the first insulating layer 141 to cover the first metal pattern 151 and the second metal pattern 152.

The second insulating layer 142 may be an insulating layer that is substantially the same as the first insulating layer 141. For example, the second insulating layer 142 may include a silicon oxide, a silicon nitride, or a low-permittivity material, like SiO₂, Si₃N₄, or SiOₓN_{y}.

Referring to FIG. 1, metal patterns 171 and 172 may be disposed on the second insulating layer 142. Specifically, a third metal pattern 171 and a fourth metal pattern 172 may be disposed on an upper surface of the second insulating layer 142.

The third metal pattern 171 and the fourth metal pattern 172 may be disposed to be spaced from each other. Specifically, the third metal pattern 171 and the fourth metal pattern 172 may be disposed to be spaced from each other on the upper surface of the second insulating layer 142. More specifically, the third metal pattern 171 may be disposed so that at least a portion thereof overlaps the first metal pattern 151 in the direction perpendicular to the plane of the substrate 110, and the fourth metal pattern 172 may be disposed so that at least a portion thereof overlaps the second metal pattern 152 in the direction perpendicular to the plane of the substrate 110.

Referring to FIG. 1, vias 163 and 164 may be disposed between the metal patterns 151 and 152 disposed on the upper surface of the first insulating layer 141 and the metal patterns 171 and 172 disposed on the upper surface of the second insulating layer 142. Specifically, a third via 163 may be disposed to pass through the second insulating layer 142 between the first metal pattern 151 and the third metal pattern 171, and a fourth via 164 may be disposed to pass through the second insulating layer 142 between the second metal pattern 152 and the fourth metal pattern 172.

The third via 163 and the fourth via 164 may include substantially the same material as the first via 161 and the second via 162. Accordingly, the third via 163 may be a conductive via and may electrically connect the first metal pattern 151 and the third metal pattern 171, and the fourth via 164 may be a conductive via and may electrically connect the second metal pattern 152 and the fourth metal pattern 172. That is, the third via 163 may electrically connect the first electrode and the first pad 181 corresponding to the first electrode by electrically connecting the first metal pattern 151 and the third metal pattern 171, and the fourth via 164 may electrically connect the second electrode and the second pad 182 corresponding to the second electrode by electrically connecting the second metal pattern 152 and the fourth metal pattern 172.

Referring to FIG. 1, a third insulating layer 143 may be disposed on the third metal pattern 171 and the fourth metal pattern 172. Specifically, the third insulating layer 143 may be disposed on the second insulating layer 142 to cover the third metal pattern 171 and the fourth metal pattern 172.

The third insulating layer 143 may include various insulating materials. Specifically, the third insulating layer 143 may include an inorganic insulating material. For example, the third insulating layer 143 may include SiO₂, Si₃N₄, or SiOₓN_{y}. In some cases, the third insulating layer 143 may include a low-permittivity material.

Referring to FIG. 1, a fourth insulating layer 144 may be disposed on the third insulating layer 143. Specifically, the fourth insulating layer 144 may be disposed to cover an upper surface of the third insulating layer 143.

The fourth insulating layer 144 may include various insulating materials. Specifically, the fourth insulating layer 144 may be an organic insulating layer or a passivation layer. For example, the fourth insulating layer 144 may include Si₃N₄, SiO₂, SiON, Al₂O₃, polyimide (PI), benzocyclobutene (BCB), spin-on-glass (SOG), or SiOC.

Referring to FIG. 1, the pads 181 and 182 may be disposed on the fourth insulating layer 144. Specifically, the first pad 181 and the second pad 182 may be disposed on an upper surface of the fourth insulating layer 144.

The first pad 181 and the second pad 182 may be disposed to be spaced from each other. Specifically, the first pad 181 may be disposed so that at least a partial region thereof overlaps the third metal pattern 171 in the direction perpendicular to the plane of the substrate 110, and the second pad 182 may be disposed so that at least a partial region thereof overlaps the fourth metal pattern 172 in the direction perpendicular to the plane of the substrate 110.

The pads 181 and 182 may be electrically connected to the metal patterns 171 and 172. Specifically, the pads 181 and 182 may be directly connected to the metal patterns 171 and 172 by passing through the third insulating layer 143 and the fourth insulating layer 144. In some cases, the pads 181 and 182 may be connected to the metal patterns 171 and 172 through vias disposed between the metal patterns 171 and 172 and the pads 181 and 182.

The first pad 181 and the second pad 182 may be electrically connected to at least one metal layer among the metal layers 120. Specifically, the first pad 181 may be electrically connected to the first electrode among the metal layers 120, and the second pad 182 may be electrically connected to the second electrode among the metal layers 120.

According to various embodiments of the present disclosure, the pads 181 and 182 may be disposed on the upper surface of the second insulating layer 142. Specifically, on the upper surface of the second insulating layer 142, the pads 181 and 182 may be directly connected to the metal patterns 151 and 152 by passing through the second insulating layer 142. In some cases, the pads 181 and 182 may be connected to the metal patterns 151 and 152 through vias disposed between the metal patterns 151 and 152 and the pads 181 and 182.

By including the floating metal layer disposed between the first electrode and the second electrode, the capacitor 100 according to one embodiment of the present disclosure can distribute the electric field and voltage applied to the dielectric layers 130 and can mitigate electric field distribution. Accordingly, by including the floating metal layer that mitigates electric field distribution between the electrodes, the capacitor 100 can suppress local electric field concentration and can reduce the possibility of dielectric breakdown in the dielectric layers. As a result, breakdown voltage and withstand voltage characteristics of the capacitor 100 can be improved, and insulation reliability and service life of elements of the capacitor 100 can be increased.

Also, by including one or more floating metal layers disposed at uniform intervals, the first electrode, and the second electrode, the capacitor 100 according to one embodiment of the present disclosure can equally distribute the applied voltage to the plurality of dielectric layers 130. Accordingly, the capacitor 100 can prevent the problem in which an electric field is concentrated on the dielectric layer 130 at a specific layer and local dielectric breakdown occurs.

Further, by including the floating metal layer that is penetrated together with the second electrode, the capacitor 100 according to one embodiment of the present disclosure can mitigate an electric field intensity concentrated on portions around the through-hole of the second electrode. Accordingly, by suppressing a local electric field concentration phenomenon at an edge of the through-hole, the capacitor 100 can reduce the risk of dielectric breakdown in the corresponding region.

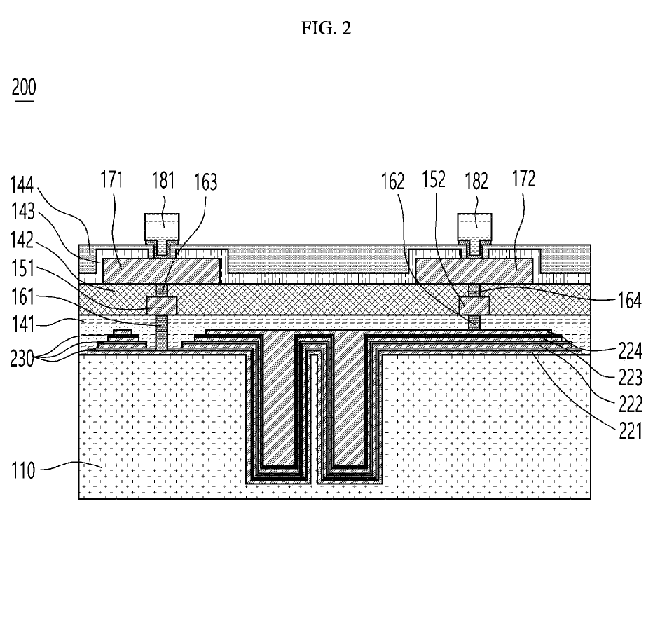

FIG. 2 is a cross-sectional view for describing a capacitor including an extending floating metal layer according to another embodiment of the present disclosure.

Referring to FIG. 2, a capacitor 200 according to the present embodiment may be different from the capacitor 100 of FIG. 1 in that a floating metal layer is configured to have a wider area than a first electrode or a second electrode. Accordingly, repeated description of substantially the same configuration as the capacitor 100 of FIG. 1 will be omitted.

Referring to FIG. 2, when viewed from an upper surface of a substrate 110, the area of the floating metal layer may be larger than the area of the first electrode or the second electrode. Specifically, a second metal layer 222 or a third metal layer 223, which is the floating metal layer, may be formed to extend past a first metal layer 221 or a fourth metal layer 224 on the plane. That is, the floating metal layer may be disposed to protrude outward past an edge of the first electrode or the second electrode.

In some cases, in the planar direction of the substrate 110, an area of a through-hole formed in the floating metal layer may be smaller than an area of a through-hole formed in the first electrode or the second electrode. Specifically, a through-hole of the second metal layer 222 or the third metal layer 223, which is the floating metal layer, may be disposed inward from a through-hole of the fourth metal layer 224. That is, an edge of the through-hole of the floating metal layer may be disposed to extend inward from an edge of the through-hole of the second electrode.

The through-holes formed in the floating metal layer and the electrodes may be through-holes through which a first via 161 passes. For example, the first via 161 may be connected to the first metal layer 221 by passing through the through-holes formed in the second metal layer 222, the third metal layer 223, and the fourth metal layer 224.

By including the floating metal layer formed to have a wider area than the first electrode or the second electrode, the capacitor 200 according to one embodiment of the present disclosure can improve the breakdown voltage and withstand voltage characteristics. An electric field may easily concentrate on an edge of an electrode of a capacitor, and thus dielectric breakdown of a dielectric layer may mostly occur at the edge of the electrode of the capacitor. On the other hand, by including the floating metal layer disposed to extend outward from an edge of the first electrode or the second electrode, the capacitor 200 according to one embodiment of the present disclosure can effectively mitigate the electric field concentrated on the edge of the electrode. Therefore, the capacitor 200 can reduce the risk of dielectric breakdown that may occur around the edge of the electrode.

Also, by including the floating metal layer disposed to extend inward from the through-hole of the first electrode or the second electrode, the capacitor 200 according to one embodiment of the present disclosure can block and distribute the electric field concentrated around the through-hole. Therefore, the capacitor 200 can reduce the risk of dielectric breakdown that may occur around the through-hole of the electrode.

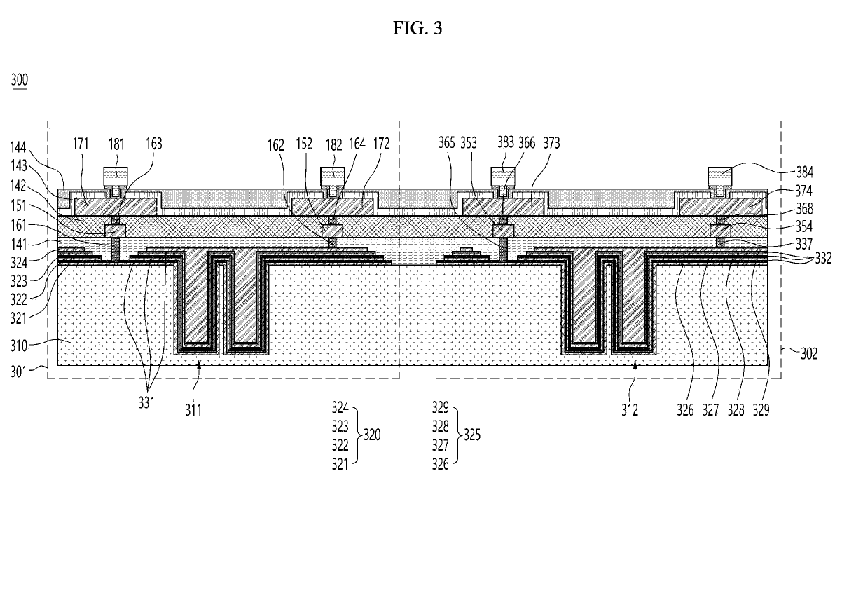

FIG. 3 is a cross-sectional view for describing a capacitor including a floating metal layer connected to another floating metal layer according to still another embodiment of the present disclosure.

Referring to FIG. 3, a capacitor 300 according to the present embodiment may further include a second trench capacitor 302 in addition to a first trench capacitor 301, which corresponds to the configuration of the capacitor 100 of FIG. 1, and may be configured so that a floating metal layer of the first trench capacitor 301 and a floating metal layer of the second trench capacitor 302 are connected. Accordingly, repeated description of substantially the same configuration as the capacitor 100 of FIG. 1 will be omitted.

Referring to FIG. 3, a substrate 310 may include a plurality of trenches formed on one surface. Specifically, the substrate 310 may include a plurality of trenches formed to be spaced from each other on an upper surface. For example, the substrate 310 may include at least one first trench 311 in which the first trench capacitor 301 is disposed and at least one second trench 312 in which the second trench capacitor 302 is disposed.

Referring to FIG. 3, the first trench capacitor 301 may include metal layers 320 and dielectric layers 331 disposed in the first trench 311, and the second trench capacitor 302 may include additional metal layers 325 and additional dielectric layers 332 disposed in the second trench 312. The first trench capacitor 301 and the second trench capacitor 302 may each include substantially the same configuration as the capacitor 100 of FIG. 1.

The first trench capacitor 301 and the second trench capacitor 302 may be disposed to be spaced from each other. Specifically, electrodes 321 and 324, metal patterns 151, 152, 171, and 172, and pads 181 and 182 of the first trench capacitor 301 may be disposed to be physically spaced from additional electrodes 326 and 329, additional metal patterns 353, 354, 373, and 374, and additional pads 383 and 384 of the second trench capacitor 302.

According to various embodiments of the present invention, the first trench capacitor 301 and the second trench capacitor 302 may be connected in parallel or series. Specifically, by the metal patterns 151, 152, 171, and 172 and the pads 181 and 182 of the first trench capacitor 301 and the additional metal patterns 353, 354, 373, and 374, and the additional pads 383 and 384 of the second trench capacitor 302 being electrically connected, the first trench capacitor 301 and the second trench capacitor 302 may be connected in parallel or series. For example, by a third metal pattern 171 of the first trench capacitor 301 and an additional third metal pattern 373 of the second trench capacitor 302 being electrically connected, and a fourth metal pattern 172 of the first trench capacitor 301 and an additional fourth metal pattern 374 of the second trench capacitor 302 being electrically connected, the first trench capacitor 301 and the second trench capacitor 302 may be connected in parallel. In some cases, by the fourth metal pattern 172 of the first trench capacitor 301 and the additional third metal pattern 373 of the second trench capacitor 302 being electrically connected, the first trench capacitor 301 and the second trench capacitor 302 may be connected in series.

The additional metal layers 325 may consist of at least three metal layers. Specifically, the additional metal layers 325 may consist of four metal layers that are sequentially stacked. For example, the additional metal layers 325 may consist of a fifth metal layer 326, a sixth metal layer 327, a seventh metal layer 328, and an eighth metal layer 329.

The additional metal layers 325 may have substantially the same configuration as the metal layers 120 of FIG. 1 and the metal layers 320 of FIG. 3. That is, the fifth metal layer 326 may be a first electrode of the second trench capacitor 302, the eighth metal layer 329 may be a second electrode of the second trench capacitor 302, and the sixth metal layer 327 or the seventh metal layer 328 may be a floating metal layer.

Referring to FIG. 3, a floating metal layer may be connected to another floating metal layer. Specifically, the floating metal layer of the first trench capacitor 301 and the floating metal layer of the second trench capacitor 302 may be connected to each other. More specifically, a second metal layer 322 or a third metal layer 323, which is the floating metal layer of the first trench capacitor 301, may be connected to the sixth metal layer 327 or the seventh metal layer 328, which is the floating metal layer of the second trench capacitor 302. For example, the second metal layer 322 of the first trench capacitor 301 and the sixth metal layer 327 of the second trench capacitor 302 may be integrally formed. In some cases, the second metal layer 322 and the sixth metal layer 327 may be connected through wiring. In some cases, the floating metal layer of the first trench capacitor 301 may be connected to another floating metal layer disposed on the substrate through a wiring or a via.

Referring to FIG. 3, the additional dielectric layers 332 may be disposed between the additional metal layers 325. For example, the additional dielectric layers 332 may be disposed between the fifth metal layer 326 and the sixth metal layer 327, between the sixth metal layer 327 and the seventh metal layer 328, and between the seventh metal layer 328 and the eighth metal layer 329. That is, the additional metal layers 325 and the additional dielectric layers 332 may be alternately stacked in the second trench 312 of the substrate 310.

The additional dielectric layers 332 may have substantially the same configuration as the dielectric layers 130 of FIG. 1 and the dielectric layers 331 of FIG. 3. That is, the additional dielectric layers 332 may be capacitor dielectrics that are formed through the ALD process and include a silicon oxide, a silicon nitride, or a high-permittivity material.

At least any one of the dielectric layers 331 of the first trench capacitor 301 and at least any one of the additional dielectric layers 332 of the second trench capacitor 302 may be connected to each other. Specifically, the dielectric layer 331 of the first trench capacitor 301 and the additional dielectric layer 332 of the second trench capacitor 302 may be integrally formed. In some cases, the dielectric layer 331 and the additional dielectric layer 332 may be connected to each other through a separate insulating layer or dielectric layer.

By including the floating metal layer connected to another floating object, the capacitor 300 according to one embodiment of the present disclosure can more stably maintain a floating potential. Accordingly, by including the floating metal layer having a stable floating potential, the capacitor 300 can more efficiently distribute the electric field and voltage between electrodes.

Also, by including the plurality of trench capacitors 301 and 302 of which the floating metal layers are connected to each other, the capacitor 300 according to one embodiment of the present disclosure can simultaneously improve the withstand voltage characteristics of both trench capacitors. When a plurality of trench capacitors are simply connected in series, a problem in which dielectric breakdown occurs first in a trench capacitor with a relatively low withstand voltage characteristic may occur. On the other hand, by simultaneously improving the withstand voltage characteristics of both trench capacitors through the floating metal layers, the capacitor 300 according to one embodiment of the present disclosure can prevent the problem of occurrence of dielectric breakdown that is limited to some elements.

Also, because the floating metal layers of both trench capacitors 301 and 302 are connected to each other even when the plurality of trench capacitors 301 and 302 are connected in parallel, the capacitor 300 according to one embodiment of the present disclosure can simultaneously improve the withstand voltage characteristics of individual trench capacitors 301 and 302. Accordingly, the withstand voltage characteristic of the entire capacitor 300 can be improved.

Also, by connecting the floating metal layers of both trench capacitors 301 and 302 to each other while connecting the plurality of trench capacitors 301 and 302 in series, the capacitor 300 according to one embodiment of the present disclosure can more significantly improve the withstand voltage characteristic of the entire capacitor 300 while preventing the dielectric breakdown problem that may occur only in some trench capacitors.

Also, the capacitor 300 according to one embodiment of the present disclosure can improve the breakdown voltage and withstand voltage characteristics without a separate additional process. Specifically, by omitting some of the patterning process for a region between the plurality of trench capacitors 301 and 302 formed on a single substrate 310, the floating metal layers and the dielectric layers can be continuously formed on the capacitor 300. Accordingly, the capacitor 300 can simultaneously improve the breakdown voltage and withstand voltage characteristics while reducing the manufacturing cost and time through a rather simplified manufacturing process.

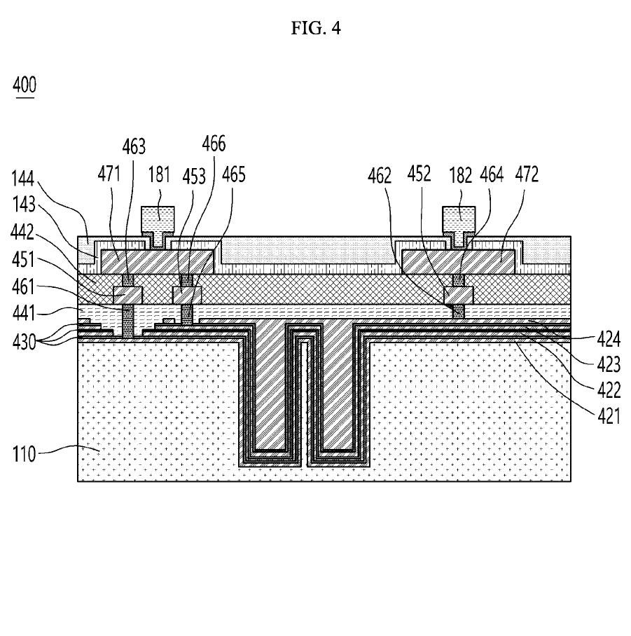

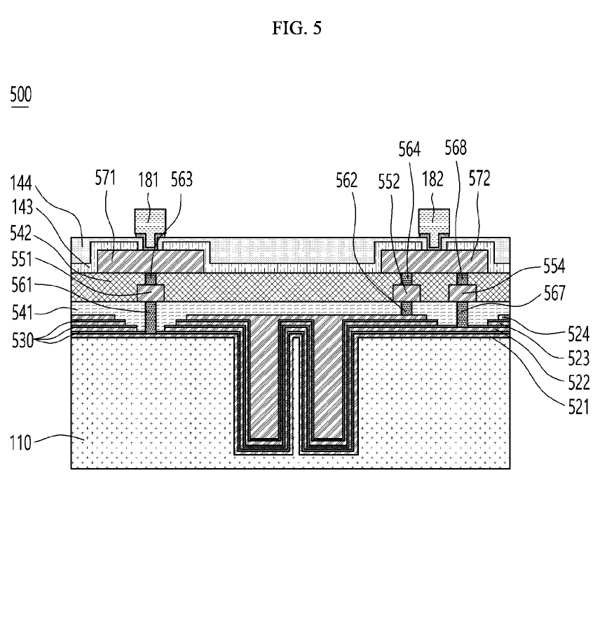

FIG. 4 is a cross-sectional view for describing a capacitor in which a floating metal layer is disposed between electrodes connected to each other according to yet another embodiment of the present disclosure. FIG. 5 is a cross-sectional view for describing another capacitor in which a floating metal layer is disposed between electrodes connected to each other according to yet another embodiment of the present disclosure.

Referring to FIGS. 4 and 5, capacitors 400 and 500 according to the present embodiments may further include additional metal patterns 453 and 554 and additional vias 465 and 567 in addition to the configuration of the capacitor 100 of FIG. 1 and may be configured so that the additional metal patterns 453 and 554 and the additional vias 465 and 567 connect one metal layer and another metal layer of the capacitors 400 and 500. Accordingly, repeated description of substantially the same configuration as the capacitor 100 of FIG. 1 will be omitted.

Referring to FIGS. 4 and 5, metal layers 420 and 520 may consist of a first electrode, a second electrode, at least one additional electrode, and at least one floating metal layer. For example, as illustrated in FIG. 4, the metal layers 420 may consist of a first metal layer 421 which is the first electrode, a second metal layer 422 which is a floating electrode, a third metal layer 423 which is a first additional electrode, and a fourth metal layer 424 which is the second electrode. Also, as illustrated in FIG. 5, the metal layers 520 may consist of a first metal layer 521 which is the first electrode, a second metal layer 522 which is a second additional electrode, a third metal layer 523 which is a floating electrode, and a fourth metal layer 524 which is the second electrode.

Referring to FIGS. 4 and 5, an additional electrode may be electrically connected to any one of the first electrode and the second electrode. Specifically, by being electrically connected to any one of the first electrode and the second electrode, the additional electrode may serve as a single electrode with the connected electrode. For example, as illustrated in FIG. 4, by the third metal layer 423, which is the first additional electrode, being electrically connected to the first metal layer 421 which is the first electrode, both the first additional electrode and the first electrode may be connected to the first pad 181 and may serve as a single first electrode. Also, as illustrated in FIG. 5, by the second metal layer 522, which is the second additional electrode, being electrically connected to the fourth metal layer 524 which is the second electrode, both the second additional electrode and the second electrode may be connected to the second pad 182 and may serve as a single second electrode.

Referring to FIGS. 4 and 5, a floating metal layer may be disposed between an additional electrode and the first electrode or the second electrode. For example, as illustrated in FIG. 4, the second metal layer 422 which is the floating metal layer may be disposed between the third metal layer 423 which is the first additional electrode and the first metal layer 421 which is the first electrode. Also, as illustrated in FIG. 5, the third metal layer 523 which is the floating metal layer may be disposed between the second metal layer 522 which is the second additional electrode and the fourth metal layer 524 which is the second electrode. Accordingly, by including a floating metal layer disposed between a plurality of electrodes that serve as the same electrode, a capacitor 400 according to one embodiment of the present disclosure can mitigate electric field concentration and reduce the risk of dielectric breakdown in the corresponding region. Also, because the floating metal layer acts as an electric field shielding layer, electric field interference from an adjacent electrode or external noise can be effectively blocked. Therefore, the capacitor 400 can secure stable electric field distribution and maintain high reliability even in a high-voltage driving environment.

In some cases, a floating metal layer may also be disposed between the third metal layer 423 which is the first additional electrode and the fourth metal layer 424 which is the second electrode. Also, a floating metal layer may also be disposed between the second metal layer 522 which is the second additional electrode and the first metal layer 521 which is the first electrode.

Referring to FIGS. 4 and 5, the additional metal patterns 453 and 554 may be disposed on first insulating layers 441 and 541. Specifically, the additional metal patterns 453 and 554 may be disposed to be spaced from first metal patterns 451 and 551 and second metal patterns 452 and 552 on upper surfaces of the first insulating layers 441 and 541. More specifically the additional metal patterns 453 and 554 may be disposed on the upper surfaces of the first insulating layers 441 and 541 so that at least some regions thereof overlap any one of third metal patterns 471 and 571 and fourth metal patterns 472 and 572 in the direction perpendicular to the plane of the substrate 110. For example, as illustrated in FIG. 4, a first additional metal pattern 453 may be disposed on the upper surface of the first insulating layer 441 to overlap the third metal pattern 471 in the direction perpendicular to the plane of the substrate 110. Also, as illustrated in FIG. 5, a second additional metal pattern 554 may be disposed on the upper surface of the first insulating layer 541 to overlap the fourth metal pattern 572 in the direction perpendicular to the plane of the substrate 110.

Referring to FIGS. 4 and 5, additional vias 465, 466, 567, and 568 may be disposed between the metal layers 520 and the additional metal patterns 453 and 554 and between the additional metal patterns 453 and 554 and the third metal patterns 471 and 571 or the fourth metal patterns 472 and 572. For example, as illustrated in FIG. 4, a first additional via 465 may be disposed between the third metal layer 423 and the first additional metal pattern 453, and a second additional via 466 may be disposed between the first additional metal pattern 453 and the third metal pattern 471. Also, as illustrated in FIG. 5, a third additional via 567 may be disposed between the second metal layer 522 and the second additional metal pattern 554, and a fourth additional via 568 may be disposed between the second additional metal pattern 554 and the fourth metal pattern 572.

The additional vias 465, 466, 567, and 568 may include substantially the same material as the first via 161 of FIG. 1. Accordingly, the additional vias 465, 466, 567, and 568 may be conductive vias and may electrically connect the additional electrodes to the additional metal patterns 453 and 554 and the pads 181 and 182. For example, as illustrated in FIG. 4, the third metal layer 423 which is the first additional electrode may be connected to the first additional metal pattern 453 through the first additional via 465 and may be connected to the third metal pattern 471, the first pad 181, and the first electrode through the second additional via 466.

By including a floating metal layer disposed between a plurality of electrodes that serve as the same electrode, the capacitor 400 according to one embodiment of the present disclosure can mitigate electric field concentration and reduce the risk of dielectric breakdown in the corresponding region. Also, by including the floating metal layer that acts as an electric field shielding layer, the capacitor 400 can effectively block electric field interference from an adjacent electrode or external noise. Therefore, the capacitor 400 can secure stable electric field distribution and maintain high reliability even in a high-voltage driving environment.

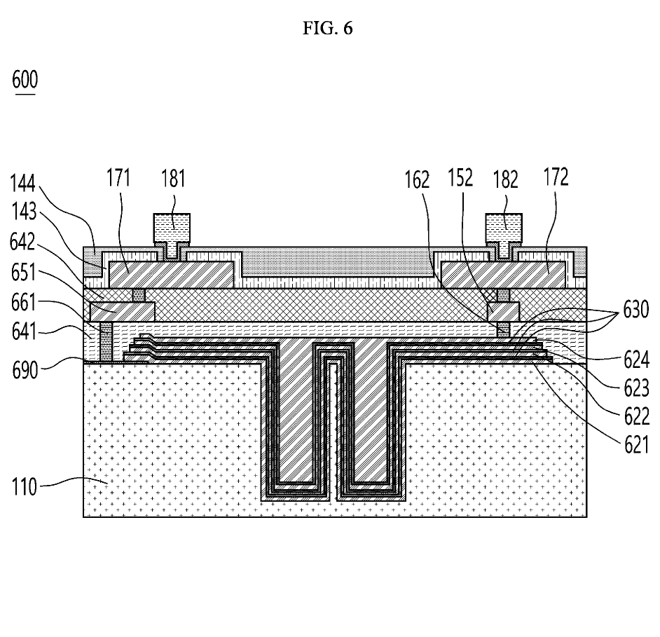

FIG. 6 is a cross-sectional view for describing a capacitor in which a conductor is disposed on an upper surface of a substrate according to yet another embodiment of the present disclosure.

Referring to FIG. 6, a capacitor 600 according to the present embodiment may further include a conductive layer 690 in addition to the configuration of the capacitor 100 of FIG. 1 and may be configured so that a first electrode is connected to the first pad 181 through the conductive layer 690. Accordingly, repeated description of substantially the same configuration as the capacitor 100 of FIG. 1 will be omitted.

Referring to FIG. 6, the conductive layer 690 may be disposed on an upper surface of a substrate 110. Specifically, the conductive layer 690 may be disposed on the upper surface of the substrate 110 to come into contact with a first metal layer 621. For example, the conductive layer 690 may be disposed on the upper surface of the substrate 110, and the first metal layer 621 may be disposed in a partial region of an upper surface of the conductive layer 690. In some cases, the conductive layer 690 may be disposed on the upper surface of the substrate 110 to be connected to one side end of the first metal layer 621. According to various embodiments of the present disclosure, the conductive layer 690 may be integrally formed with the first metal layer 621. That is, the conductive layer 690 may be a region in which the first metal layer 621 extends outward past other metal layers.

The conductive layer 690 may be disposed to extend in an outward direction of the capacitor 600. Specifically, the conductive layer 690 may extend from edges of metal layers 620 toward an outer side end of the capacitor 600. In some cases, the conductive layer 690 may be disposed to extend to one side end of the capacitor 600 or a region between a plurality of capacitors in the planar direction of the substrate 110.

Referring to FIG. 6, a first via 661 may be disposed between the conductive layer 690 and metal patterns 651 and 171. Specifically, the first via 661 may be disposed to pass through a first insulating layer 641 between the conductive layer 690 and a first metal pattern 651. In some cases, the first via 661 may be disposed to pass through the first insulating layer 641 and a second insulating layer 642 between the conductive layer 690 and a third metal pattern 171. More specifically, the first via 661 may be spaced from the edges of the metal layers 620 in a direction toward the outer side end of the capacitor 600 and may be disposed between the conductive layer 690 and the metal patterns 651 and 171.

The first via 661 may include substantially the same material as the first via 161 of FIG. 1. Accordingly, the first via 661 may be a conductive via and may electrically connect the conductive layer 690 and the first metal pattern 651. That is, the first via 661 may electrically connect the first metal layer 621, which is the first electrode, to the first metal pattern 651 and the first pad 181 by electrically connecting the conductive layer 690 and the first metal pattern 651. In some cases, the first via 661 may electrically connect the conductive layer 690 and the first pad 181 by being disposed between the conductive layer 690 and the third metal pattern 171 or being disposed between the conductive layer 690 and the first pad 181. Accordingly, by including the conductive layer 690 that connects the first electrode and the first pad 181, the capacitor 600 according to one embodiment of the present disclosure can electrically connect the first electrode to the first pad 181 and the outside without forming a via that passes through metal layers 622, 623, and 624. Therefore, by simplifying a via formation process, the capacitor 600 can simplify a manufacturing process and improve process yield.

According to another embodiment of the present disclosure, the conductive layer 690 may be electrically connected to the first pad 181 through wiring formed along an outer side surface of the capacitor 600. Specifically, the wiring disposed along the outer side surface of the capacitor may have one side that comes into contact with the conductive layer 690 and another side that comes into contact with the first metal pattern 651, a third metal pattern 171, or the first pad 181, and in this way, the first electrode may be electrically connected to the first pad 181 through the conductive layer 690 and the side surface wiring. In such a case, the second electrode may also be electrically connected to the second pad 182 through the wiring disposed along the side surface of the capacitor 600. Specifically, a fourth metal layer 624, which is the second electrode, may extend in the outward direction of the capacitor 600, or the conductive layer disposed on an upper portion of the fourth metal layer 624 may extend in the outward direction of the capacitor 600, and in this way, the second electrode may be connected to the second pad 182 through the side surface wiring.

Accordingly, by including the side surface wiring that electrically connects the electrodes and the pads 181 and 182 without a via passing through the pads 181 and 182 and the metal layers 620, the capacitor 600 according to one embodiment of the present disclosure can omit or simplify a via formation process. Also, because a wiring path between the electrodes and the pads 181 and 182 of the capacitor 600 can be designed in various ways on a plane, a degree of freedom of wiring and layout design flexibility can be improved. Therefore, by including the side surface wiring that electrically connects the electrodes and the pads 181 and 182, the capacitor 600 can improve an integration density and process yield through layout optimization while reducing complexity of a manufacturing process.

According to yet another embodiment of the present disclosure, the conductive layer 690 may be electrically connected to the first pad 181 disposed on an outer side surface of the capacitor 600. Specifically, the first pad 181 may be disposed on the outer side surface of the capacitor 600, and the conductive layer 690 may be disposed to directly come into contact with the first pad 181. Accordingly, the first electrode can be connected to the first pad 181 through the conductive layer 690 without separate wiring between the conductive layer 690 and the first pad 181. By including the conductive layer 690 that connects the pads 181 and 182 directly formed on the outer side surface of the capacitor 600 and the electrodes, the capacitor 600 according to one embodiment of the present disclosure can secure electrical connection with a simple structure without an additional wiring formation or via formation process. Therefore, by minimizing a vertical thickness of the entire element, the capacitor 600 can implement a high-integration capacitor element. Also, by omitting separate wiring and vias, the capacitor 600 can reduce the possibility of wiring defects or via defects and can improve manufacture reliability and process yield of the element.

Also, by omitting etching and via formation processes for the metal layers 622, 623, and 624 on an upper portion of the first electrode, the capacitor 600 according to one embodiment of the present disclosure can lower the process complexity and reduce the risk of process defects such as electrode damage or photoresist contamination that may occur in the etching process.

Further, by reducing an inactive region for forming a via in the metal layers 620 and expanding a region for placing a trench correspondingly, the capacitor 600 according to one embodiment of the present disclosure can secure a higher capacitance in the same area. Therefore, the capacitor 600 can maximize the capacitance per area while improving stability of a manufacturing process.

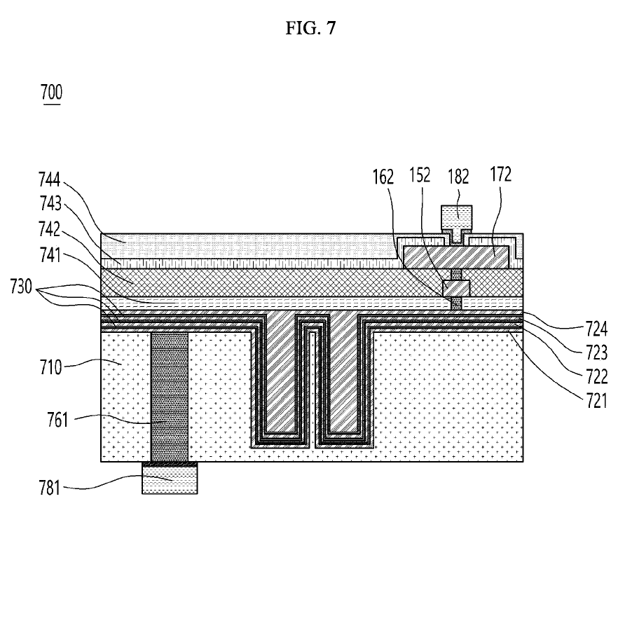

FIG. 7 is a cross-sectional view for describing a capacitor in which a via passing through a substrate is disposed according to yet another embodiment of the present disclosure.

Referring to FIG. 7, a capacitor 700 according to the present embodiment may have a first pad 781 disposed on a lower surface of a substrate 710 in the configuration of the capacitor 100 of FIG. 1 and may be configured so that a first via 761 passes through the substrate 710. Accordingly, repeated description of substantially the same configuration as the capacitor 100 of FIG. 1 will be omitted.

Referring to FIG. 7, the first pad 781 may be disposed on one surface of the substrate 710. Specifically, the first pad 781 may be disposed on the opposite surface of a surface on which a trench is formed. For example, a trench may be formed on an upper surface of the substrate 710, and the first pad 781 may be disposed on a lower surface of the substrate 710.

Referring to FIG. 7, the first via 761 may be disposed between the first pad 781 and a first electrode. Specifically, the first via 761 may be disposed to pass through the substrate 710 between the first pad 781 and a first metal layer 721 which is the first electrode. That is, the first via 761 may be a through-silicon via (TSV).

The first via 761 may include a conductive material. The first via 761 may be a conductive via and may electrically connect the first pad 781 and the first electrode. For example, the first via 761 may electrically connect the first pad 781 and the first metal layer 721 which is the first electrode.

By including the pad 781 disposed on a lower portion of the substrate 710 and the via 761 that passes through the substrate, the capacitor 700 according to one embodiment of the present disclosure can reduce wiring complexity of an upper space. Also, the capacitor 700 can simplify an upper passivation region or minimize interference between the second pad 182 and metal layers 720. Therefore, the capacitor 700 can improve the overall area efficiency and degree of freedom of design.

Also, by omitting etching and via formation processes for metal layers 722, 723, and 724 on an upper portion of the first electrode, the capacitor 700 according to one embodiment of the present disclosure can lower the process complexity and reduce the risk of process defects such as electrode damage or photoresist contamination that may occur in the etching process.

Further, by reducing an inactive region for forming a via in the metal layers 720 and expanding a region for placing a trench correspondingly, the capacitor 700 according to one embodiment of the present disclosure can secure a higher capacitance in the same area. Therefore, the capacitor 700 can maximize the capacitance per area while improving stability of a manufacturing process.

According to any one of the problem solving means of the present disclosure, a capacitor includes dielectric layers formed through an atomic layer deposition (ALD) process, thereby improving film quality uniformity of the dielectric layers throughout a trench structure.

According to any one of the problem solving means of the present disclosure, a capacitor includes a floating metal layer disposed between dielectric layers, thereby securing an excellent withstand voltage characteristic and insulation reliability even in a structure including thin dielectric layers.

According to any one of the problem solving means of the present disclosure, a capacitor includes one or more floating metal layers disposed at uniform intervals, thereby preventing a problem in which an electric field is concentrated on a dielectric layer at a specific layer and local dielectric breakdown occurs.

According to any one of the problem solving means of the present disclosure, a capacitor includes a floating metal layer that is penetrated together with an electrode, thereby mitigating an electric field intensity concentrated on portions around a through-hole and reducing the risk of dielectric breakdown in the corresponding region.

Advantageous effects that can be obtained from the present disclosure are not limited to those mentioned above, and other unmentioned advantageous effects should be clearly understood by those of ordinary skill in the art to which the present disclosure pertains from the description above.

Although embodiments of the present disclosure have been described in more detail above with reference to the accompanying drawings, the present disclosure is not necessarily limited to these embodiments and may be modified in various ways without departing from the technical spirit of the present disclosure. Accordingly, the embodiments disclosed in the present disclosure are for describing, instead of limiting, the technical spirit of the present disclosure, and the scope of the technical spirit of the present disclosure is not limited by these embodiments. Therefore, the above-described embodiments should be understood as being illustrative, instead of limiting, in all aspects. The protection scope of the present disclosure should be construed based on the appended claims, and all the technical concepts in the equivalent scope thereof should be construed as falling within the scope of the present disclosure.

What is claimed is:

1. A capacitor comprising:
a substrate;
at least three first metal layers disposed in a first trench formed on the substrate; and
first dielectric layers disposed between the at least three first metal layers,
wherein the at least three first metal layers consist of:
a first electrode;
a second electrode disposed on the first electrode; and
at least one first floating metal layer disposed between the first electrode and the second electrode.

2. The capacitor of claim 1, further comprising:
an insulating layer disposed on the second electrode;
a first metal pattern disposed on an upper surface of the insulating layer;
a second metal pattern disposed to be spaced from the first metal pattern on the upper surface of the insulating layer;
a first via disposed between the first metal pattern and the first electrode; and
a second via disposed between the second metal pattern and the second electrode,
wherein the first via is disposed to pass through the second electrode and the at least one first floating metal layer.

3. The capacitor of claim 1, wherein, on a plane of the substrate, an area of the at least one first floating metal layer is greater than an area of the first electrode or an area of the second electrode.

4. The capacitor of claim 1, further comprising:
a second trench disposed to be spaced from the first trench on an upper surface of the substrate;
at least three second metal layers disposed in the second trench; and
second dielectric layers disposed between the at least three second metal layers,
wherein the at least three second metal layers consist of:
a third electrode;
a fourth electrode disposed on the third electrode; and
at least one second floating metal layer disposed between the third electrode and the fourth electrode,
the at least one first floating metal layer and the at least one second floating metal layer are connected to each other through wiring or a via, and
the first electrode and the fourth electrode are electrically connected, or the second electrode and the third electrode are electrically connected.

5. The capacitor of claim 1, wherein:
the at least three first metal layers further include a fifth electrode;
the fifth electrode is electrically connected to the first electrode; and
the at least one first floating metal layer is disposed between the first electrode and the fifth electrode.

6. The capacitor of claim 1, wherein:
the at least three first metal layers further include a sixth electrode;
the sixth electrode is electrically connected to the second electrode; and
the at least one first floating metal layer is disposed between the second electrode and the sixth electrode.

7. The capacitor of claim 1, wherein:
the first electrode is a metal layer disposed at a lowermost layer among the at least three first metal layers; and
the second electrode is a metal layer disposed at an uppermost layer among the at least three first metal layers.

8. The capacitor of claim 7, further comprising:
a conductive layer disposed on the upper surface of the substrate; and
a first pad electrically connected to the first electrode,
wherein the conductive layer electrically connects the first electrode and the first pad.

9. The capacitor of claim 7, further comprising:
a third via that passes through the substrate; and
a first pad electrically connected to the first electrode,
wherein the third via electrically connects the first electrode and the first pad.

10. The capacitor of claim 9, wherein the first pad is disposed on a lower surface of the substrate.
